(19) United States
(12) Patent Application Publication
(10) Pub. No.: US 2006/0038302 A1
(43) Pub. Date: Feb. 23, 2006

(54) Thermal fatigue resistant tin-lead-silver solder

(76) Inventor: Kejun Zeng, Coppell, TX (US)

Correspondence Address: TEXAS INSTRUMENTS INCORPORATED, P O BOX 655474, M/S 3999, DALLAS, TX, 75265, US

(21) Appl. No.: 10/922,037

(22) Filed: Aug. 19, 2004

(51) Int. Cl. H01L 23/48

(52) U.S. Cl. 257/779; 257/738; 257/737; 257/772

(57) ABSTRACT

A solder comprising a ternary alloy of tin, lead, and silver, providing approximately the eutectic melting temperature and about 0.7 to 1.5 weight percent silver. In one embodiment, the ternary solder alloy comprises the composition of about 61.0 weight percent tin, about 37.5 weight percent lead, and about 1.5 percent weight percent silver. In another embodiment, the ternary solder alloy comprises the composition of about 61.3 weight percent tin, about 37.7 weight percent lead, and about 1.0 percent weight percent silver. At these silver concentrations, precipitated Ag₃Sn particles (210), embedded in the matrix of the eutectic alloy (201), can pin down (222) moving dislocations (220) and thus increase the fatigue resistance of the solder.

### FIELD OF THE INVENTION

The present invention is related in general to the field of metallurgical systems with application to electronic systems and semiconductor devices, and more specifically to fatigue-resistant ternary solder alloys.

### DESCRIPTION OF THE RELATED ART

During and after assembly of an integrated circuit (IC) chip to an external part such as a substrate, ceramic or circuit board by solder reflow, and then during device operation, significant temperature differences and temperature cycles occur between the semiconductor chip and the substrate. This is especially true of flip-chip type mounting schemes. The reliability of the solder joint is strongly influenced by the coefficients of thermal expansion of the semiconductor material and the substrate material. For example, there is more than one order of magnitude difference between the coefficients of thermal expansion of silicon and FR-4. This difference causes thermomechanical stresses, most of which are absorbed by the solder joints.

The fabrication methods and reliability problems involving flip-chips re-appear, in somewhat modified form, for ball-grid array type packages, including chip-scale packages (CSP). Most CSP approaches are based on flip-chip assembly with solder bumps or solder balls on the exterior of the package, to interface with system or wiring boards.

One commonly used method of mitigating stress-created problems is the filling of the empty space between solder connections by stress-absorbing materials. Following the solder reflow step, flip-assembled chips and packages often use a polymeric underfill between the chip, or package, and the interposer, substrate, or printed circuit board (PCB). These underfill materials alleviate some of the thermomechanical stress caused by the mismatch of the coefficients of thermal expansion (CTE) of package components. But as a process step, underfilling is time-consuming and expensive, and is preferably avoided.

The absorption of stress, and thus he tolerance for stress and the resistance against stress degradation, are weakened when dislocations appear in the solder joint. Dislocations may be caused by a variety of mechanisms such as metal diffusions, or thermomechanical stress. The propagation of dislocations is referred to as creep. It is an advantage to use solders, which contain crystallites able to stop, or trap, creep. These solders are generally referred to as thermal fatigue resistant solders.

During the last few years, it has been found that eutectic tin/lead (Sn/Pb) solder, both as prefabricated spheres and as paste, will increase its resistance against thermal fatigue, when silver (Ag) is added to the solder. Silver-rich crystallites, especially Ag₃Sn, which are embedded in the eutectic solder, act as creep stoppers. Consequently, commercially available eutectic tin/lead solder with 2 weight percent silver is now widely used in the semiconductor industry.

Unfortunately, more extended thermal cycling tests of solder-assembled bond pads of semiconductor chips have recently shown that the lifetime of joints involving Sn/Pb solder with 2 weight percent Ag is severely limited by the appearance of cracks along the solder/bond pad interface. A rapidly increasing number of samples starts failing after prolonged testing periods.

### SUMMARY OF THE INVENTION

A need has therefore arisen for a careful failure investigation and a coherent, low-cost method of assembling flip-chip integrated circuit chips and semiconductor devices that provides a high degree of thermomechanical stress reliability. The method should be flexible enough to be applied for different semiconductor product families and a wide spectrum of design and process variations. Preferably, these innovations should be accomplished using the installed equipment base so that no investment in new manufacturing machines is needed.

In a detailed reliability investigation and solder joint analysis, involving a number of different solders (K. Zeng and K. N. Tu, “Six Cases of Reliability Study of Pb-free Solder Joints in Electronic Packaging Technology”, Materials Science & Engineering, Reports, vol. R38, pp. 55-105, 2002), the inventor found the existence of large Ag₃Sn plates with smooth surfaces at the interface between the solder and the chip bond pad. Nascent cracks, which originate close to these plates, propagate along the smooth plate surface until the joint fails. The Ag₃Sn plates were caused by excess silver introduced by the 2 weight percent silver addition.

One embodiment of the invention is a fatigue-resistant solder alloy comprising a ternary alloy comprising tin, lead, and silver, wherein this alloy provides approximately the eutectic melting temperature and has about 0.7 to 1.5 weight percent silver.

In one embodiment, the ternary solder alloy comprises the composition of about 61.0 weight percent tin, about 37.5 weight percent lead, and about 1.5 percent weight percent silver. In another embodiment, the ternary solder alloy comprises the composition of about 61.3 weight percent tin, about 37.7 weight percent lead, and about 1.0 percent weight percent silver. At these silver concentrations, precipitated Ag₃Sn particles, embedded in the matrix of the eutectic alloy, can pin down moving dislocations and thus increase the fatigue resistance of the solder.

Another embodiment of the invention is an assembled semiconductor device comprising a semiconductor chip including at least one bond pad and a substrate having at least one contact pad. A metallic interconnection element is attached to the bond pad as well as the contact pad; the interconnection element comprises a ternary alloy of tin, lead, and silver, which provides approximately the eutectic melting temperature and contains about 0.7 to 1.5 weight percent silver.

Yet another embodiment of the invention is a method for the assembly of a semiconductor chip having at least one bond pad onto a substrate having at least one contact pad. The method provides an interconnection element comprising a ternary alloy of substantially eutectic tin and lead with silver added between 0.7 and 1.5 weight percent. The interconnection element is brought in contact with the bond pad and the contact pad, while solder flux is applied. Thermal energy is supplied to reflow the interconnection element at about 235° C.; energy and time are controlled to melt the interconnection element while evaporating the flux. The ternary alloy is finally cooled.

It is a technical advantage of the invention that the restricted silver content of the solder inhibits the formation of Ag₃Sn plates, which provides crack propagation, and simultaneously enhances the thermal fatigue resistance of the assembly by strengthening the creep-stopping characteristic of particulate Ag₃Sn.

The technical advances represented by the invention, as well as the aspects thereof, will become apparent from the following description of the preferred embodiments of the invention, when considered in conjunction with the accompanying drawing and the novel features set forth in the appended claims.

### BRIEF DESCRIPTION OF THE DRAWINGS

FIG. 1 shows a schematic cross section of a solder connection on a semiconductor device contact pad, wherein the solder comprises a eutectic tin/lead alloy with silver according to known technology.

FIG. 2 illustrates a schematic cross section of a solder connection on a semiconductor device contact pad, wherein the solder comprises a eutectic tin/lead alloy with silver according to an embodiment of the invention.

FIGS. 3A and 3B are schematic cross sectional magnifications of portions of the solder connection of FIG. 2, illustrating the effect of silver-containing crystallites on moving lattice dislocations according to the invention.

FIG. 3A shows schematically a lattice dislocation moving towards a plurality of silver-containing crystallites embedded in the solder.

FIG. 3B shows schematically a lattice dislocation immobilized by a plurality of silver-containing crystallites embedded in the solder.

FIG. 4 illustrates a schematic cross section of a solder connection between a semiconductor device portion and a substrate portion, wherein the solder has a composition according to an embodiment of the invention.

### DETAILED DESCRIPTION OF THE PREFERRED EMBODIMENTS

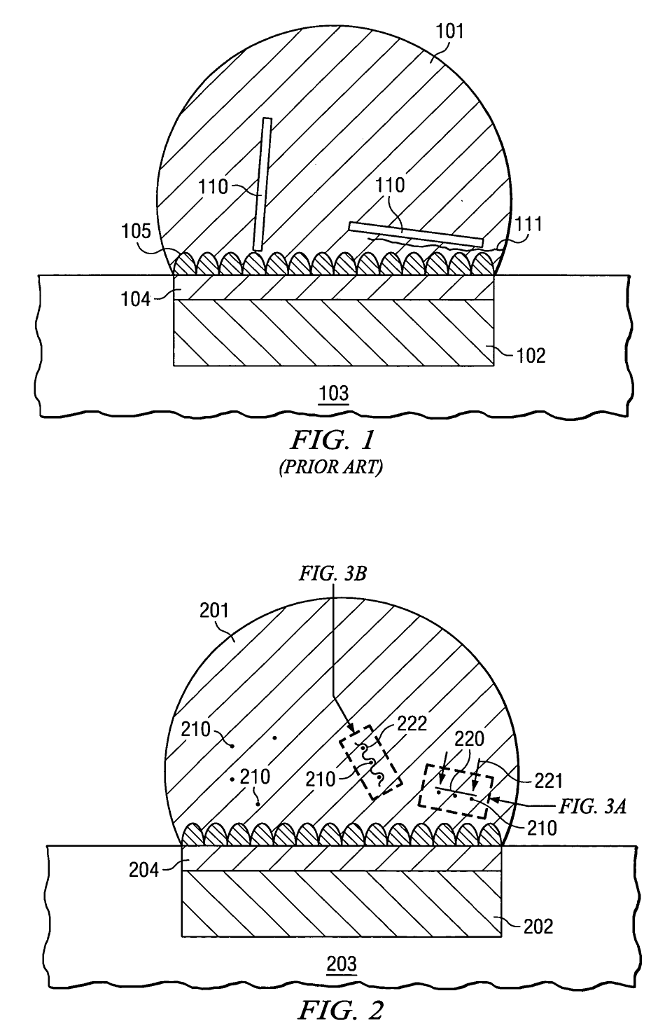

The impact of the present invention can be most easily appreciated by highlighting the shortcomings of the known technology. As a typical example of the known technology, the schematic cross section of FIG. 1 illustrates a ball (bump) 101 of tin/lead solder, alloyed with 2 weight percent silver, on a copper bond pad 102 after solder reflow. Pad 102 is embedded in insulating material 103 as part of a semiconductor device. In devices having a copper layer 104, crystalline compounds 105 with the composition Cu₆Sn₅ have formed at the interface between copper 104 and solder 101. Alternatively, in devices having a nickel layer 104, crystalline compounds 105 with the composition Ni₃Sn₄ have formed at the interface between nickel 104 and solder 101.

As FIG. 1 schematically indicates, relatively large plates 110 of the composition Ag₃Sn have formed at random locations and random orientation, especially promoted in the vicinity of the bump/pad interface. The surfaces of these plates are typically quite smooth. Consequently, they offer a favorite location for microcracks 111 to propagate from the outer bump surface along the smooth plate surface inward into the solder bump. In FIG. 1, one of these microcracks is depicted schematically along one of the silver/tin plates. These microcracks have a high probability to deteriorate into a completely open solder ball connection.

The inventor has shown in a detailed failure analysis study (K. Zeng and K. N. Tu, “Six Cases of Reliability Study of Pb-free Solder Joints in Electronic Packaging Technology”, Materials Science & Engineering, Reports, vol. R38, pp. 55-105, 2002) that the existence of large Ag₃Sn plates are a consequence of the relatively high 2 weight percent silver admixture to the eutectic tin/lead solder. The calculated eutectic ternary composition of the alloy is 1.62 weight percent silver, 36.95 weight percent lead, and 61.43 weight percent tin. To avoid Ag₃Sn plates, the silver content should be less than 1.62 weight percent.

One embodiment of the present invention is a solder comprising a ternary alloy of tin, lead, and silver, which provides approximately the eutectic melting temperature of about 179° C. and has about only 0.7 to 1.5 weight percent silver.

For example, with 1.5 weight percent silver, the ternary solder alloy comprises about 61.0 weight percent tin, and about 37.5 weight percent lead.

In another example, with 1.0 weight percent silver, the ternary solder alloy comprises the composition of about 61.3 weight percent tin and about 37.7 weight percent lead.

The cross section of FIG. 2 illustrates schematically the benefit of the invention in a ball (bump) after solder reflow.

According to the invention, with the silver concentration at a level low enough so that only hard Ag₃Sn crystallites can form, embedded in the matrix of eutectic solder structure, but not the larger Ag₃Sn plates, the ternary solder can demonstrate its full capability to entangle, pin down and block moving lattice dislocations.

FIG. 2 illustrates this technical advantage of the invention. The schematic cross section shows a ball (bump) 201 of tin/lead solder, alloyed with 0.7 to 1.5 weight percent silver, on a copper bond pad 202 after solder reflow. Pad 202 is embedded in insulating material 203 as part of a semiconductor device. In devices having a copper layer 204, crystalline compounds 205 with the composition Cu₆Sn₅ have formed at the interface between copper 204 and solder 201. Alternatively, in devices having a nickel layer 204, crystalline compounds 205 of the composition Ni₃Sn₄ have formed at the interface between nickel 204 and solder 201.

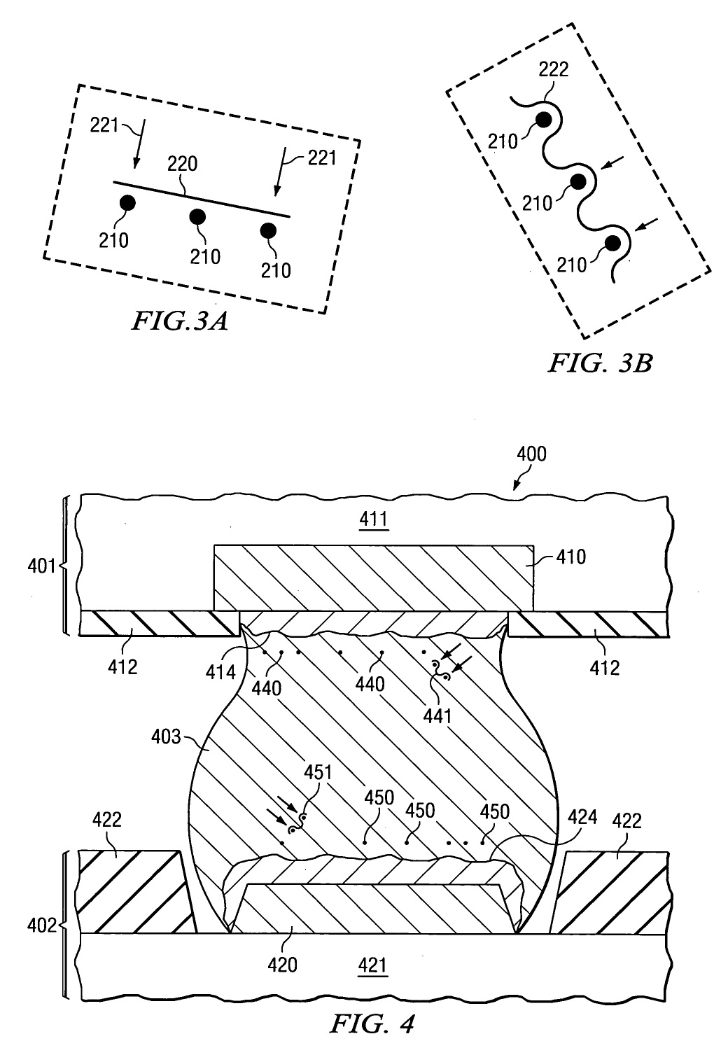

As FIG. 2 schematically indicates, small crystallites 210 of the composition Ag₃Sn have formed at many random locations, embedded in the matrix of eutectic tin/lead structure. A few of these crystallites are pulled out and shown in the schematic enlargements of FIGS. 3A and 3B. FIG. 2 further indicates a lattice dislocation 220, which happens to move in the direction indicated by arrows 221. FIG. 3A is an enlargement of this moving dislocation. FIG. 2 also shows schematically another lattice dislocation 222, which got pinned down by a group of Ag₃Sn crystallites 210; this event is enlarged in FIB. 3B. The inactivation of lattice dislocations such 222 leads to enhanced fatigue resistance of solder bump 201.

Another embodiment of the invention, illustrated schematically in part in FIG. 4, is an assembled semiconductor product generally designated 400, comprising a semiconductor device (may be a packaged device or a chip) 401 including at least one bond pad 410 (preferably copper), and a substrate 402 having at least one contact pad 420 (preferably copper). Bond pad 410 is surrounded by insulating material 411 (for example, silicon dioxide, silicon nitride, silicon carbide, low-k dielectrics, polymer compounds, glass ceramics, FR-4 or other composites); 412 is a solder mask such as polyimide or other low dielectric polymer. Contact pad 420 is surrounded by insulating material 421 such as composite FR-4, FR-5, glass-fiber reinforced polymers, or alumina. Examples for solder mask 422 are polyimides and other polymer compounds of low dielectric constant. A metallic interconnection element 403 is attached to bond pad 410 as well as to contact pad 420; the interconnection element comprises a ternary alloy of tin, lead, and silver, which provides approximately the eutectic melting temperature and contains between about 0.7 and 1.5 weight percent silver.

For assemblies having the solder connection 403 in direct contact with copper bond pad 410 and copper contact pad 420, crystalline interfaces 414 and 424 consist of Cu₆Sn₅. FIG. 4 schematically indicates the formation 440 and 450 of crystallites Ag₃Sn in many locations, not only near the device joint and the substrate joint, but throughout the solder connection 403. The technical advantage of Ag₃Sn crystallites for arresting moving dislocations is schematically indicated by designations 441 and 451. Based on the silver content between 0.7 and 1.5 weight percent according to the invention, the ternary solder 403 can fully utilize its thermal fatigue resistant characteristics.

Another embodiment of the invention is a method for the assembly of a semiconductor chip, or a semiconductor device, having at least one bond pad onto a substrate having at least one contact pad. In the first process step, the method provides an interconnection element comprising a ternary alloy of substantially eutectic tin and lead with silver added between 0.7 and 1.5 weight percent. The interconnection element is preferably a prefabricated solder ball or bump. In the next process step, the interconnection element is brought in contact with the bond pad and the contact pad, while solder flux is applied.

Thermal energy is supplied, for instance by radiation or in a throughput-oven, to reflow the interconnection element at about 235° C. (the melting temperature of the ternary alloy is about 179° C., close to the eutectic temperature). Energy and time are controlled to melt the interconnection element while evaporating the flux. Finally, the thermal energy is removed and to cool the ternary alloy interconnection. The method according to the invention produces a ternary alloy interconnection, which is substantially free of silver-rich plates, yet includes Ag₃Sn crystallites to trap lattice dislocations and renders the interconnection fatigue-resistant.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description.

It is therefore intended that the appended claims encompass any such modifications and embodiments.

I claim:

1. A fatigue-resistant solder alloy comprising:
a ternary alloy comprising tin, lead, and silver, said alloy providing approximately the eutectic melting temperature;
said alloy comprising less than 1.62 weight percent silver.

2. The solder according to claim 1 wherein said silver content comprises about 0.7 to 1.5 weight percent.

3. The solder according to claim 1 wherein said silver content is about 1.0 to 1.5 weight percent.

4. The solder alloy according to claim 1, wherein said ternary alloy comprises the composition of about 61.0 weight percent tin, about 37.5 weight percent lead, and about 1.5 percent weight percent silver.

5. The solder alloy according to claim 1, wherein said ternary alloy comprises the composition of about 61.3 weight percent tin, about 37.7 weight percent lead, and about 1.0 percent weight percent silver.

6. The solder alloy according to claim 1, wherein said melting temperature is about 179° C.

7. An assembled semiconductor device comprising:
a semiconductor chip including at least one bond pad;
a substrate having at least one contact pad; and
a metallic interconnection element attached to said bond pad and said contact pad, said interconnection element comprising a ternary alloy of tin, lead, and silver, said alloy providing approximately the eutectic melting temperature; said alloy comprising less than 1.62 weight percent silver.

8. The device according to claim 7 wherein said alloy comprises about 0.7 to 1.5 weight percent silver.

9. The device according to claim 7 wherein said interconnection element is substantially free of silver-rich tin crystallites, including Ag₃Sn.

10. A method for the assembly of a semiconductor chip having at least one bond pad onto a substrate having at least one contact pad, comprising the steps of:
providing an interconnection element comprising a ternary alloy of substantially eutectic tin and lead with silver added between 0.7 and 1.5 weight percent;
bringing said interconnection element in contact with said bond pad and said contact pad, while applying said solder flux;
supplying thermal energy to reflow said interconnection element at about 235° C.;
controlling the amount of energy and time to melt said interconnection element while evaporating said flux; and
removing said thermal energy to cool said ternary alloy interconnection.

11. The method according to claim 10 wherein said ternary alloy interconnection is substantially free of silver-rich plates, yet includes Ag₃Sn crystallites, whereby said interconnection is fatigue-resistant.
